(19) United States
(12) Patent Application Publication
(10) Pub. No.: US 2012/0014051 A1
(43) Pub. Date: Jan. 19, 2012

(54) Hermetic Seal For Portable Electronic Device

(76) Inventors: Mark David Senatori, The Woodlands, TX (US); Cameron C. Duncan, Tomball, TX (US)

(21) Appl. No.: 13/260,129

(22) PCT Filed: Nov. 12, 2009
(86) PCT No.: PCT/US09/64212

§ 371 Date: Sep. 23, 2011

(51) Int. Cl. H05K 5/00; B23P 11/00

(52) U.S. Cl. 361/679.01; 29/428

(57) ABSTRACT

Embodiments of the present invention disclose a hermetic seal apparatus for a portable electronic device. According to one embodiment, the sealing apparatus includes a first housing 102 and a second housing 104 that are connected together at a common end. A receiving member 108 is formed continuously around an interior surface of the first housing, while a receiving member 112 is formed continuously around an interior surface of the second housing. Furthermore, the engaging member is configured to fit hermetically within the receiving member so as to seal the first housing with the second housing.

### BACKGROUND

The emergence and popularity of mobile computing has made portable electronic devices, due to their compact design and light weight, a staple in today's marketplace. Many portable electronic devices employ a dam-shell type design such as notebook computers, netbooks, tablet personal computers, and handheld devices. Generally, a clam-shell design consists of two housings connected together at a common end. One problem associated with the claim-shell design of portable electronic devices is that dust, water, and other external elements may enter the surface of the device while the device is dosed, that is, when the two housings are aligned on top of each other. As a result, circuitry associated with critical components such as the liquid crystal display (LCD), keyboard, touchpad, and speakers may he affected by these external artifacts, potentially compromising the integrity of the system, or causing unnecessary cleaning or maintenance for the user.

### BRIEF OF THE DRAWINGS

The features and advantages of the inventions as well as additional features and advantages thereof will be more clearly understood hereinafter as a result of a detailed description of particular embodiments of the invention when taken in conjunction with the following drawings in which:

FIG. 1 is a three-dimensional perspective view of a notebook computer according to an embodiment of the present invention.

FIG. 2A is a three-dimensional perspective view of a notebook computer in a closed position, while FIG. 2B is a three-dimensional cross-sectional view of the notebook computer taken along line A-A′ of FIG. 2A according to an embodiment of the present invention.

FIGS. 3A-3C illustrate the hermetic sealing process of the notebook computer according to an embodiment of the present invention.

FIGS. 4A-4C illustrates the steps for automatic sealing of the top and lower housing or the notebook computer according to an embodiment of the present invention.

FIGS. 5A-5C illustrate alternative configurations oldie male engaging member and female receiving member according to embodiments of the present invention.

FIGS. 6A-6C illustrate an engagement member and receiving member according to another embodiment of the present invention.

### DETAILED DESCRIPTION OF THE INVENTION

The following discussion is directed to various embodiments. Although one or more of these embodiments may be preferred, the embodiments disclosed should not be interpreted, or otherwise used, as limiting the scope of the disclosure, including the claims. In addition, one skilled in the art will understand that the following description has broad application, and the discussion of any embodiment is meant only to be exemplary of that embodiment, and not intended to intimate that the scope of the disclosure, including the claims, is limited to that embodiment.

One solution to the aforementioned problem is to overlay a protection cover on the keyboard of the portable electronic device. However, this method adds unnecessary weight to the lower housing and may even prevent the portable electronic device from closing properly. In addition, this solution does not prevent water, dust and other elements from entering circuitry of the display panel and components other than the keyboard (e.g. track pad).

Embodiments of the present invention disclose a perimeter edge seal for external element protection of a portable electronic device having a clam-shell design. According to one embodiment, when a top housing is closed against the lower housing, a hermetic seal is formed in a gasket area of the lower housing. In particular embodiments, the hermetic seal is automatically formed once the top housing is closed against the lower housing, thereby forming a watertight area within this gasket area so as to prohibit the entrance of harmful artifacts into the interior areas of the portable electronic device.

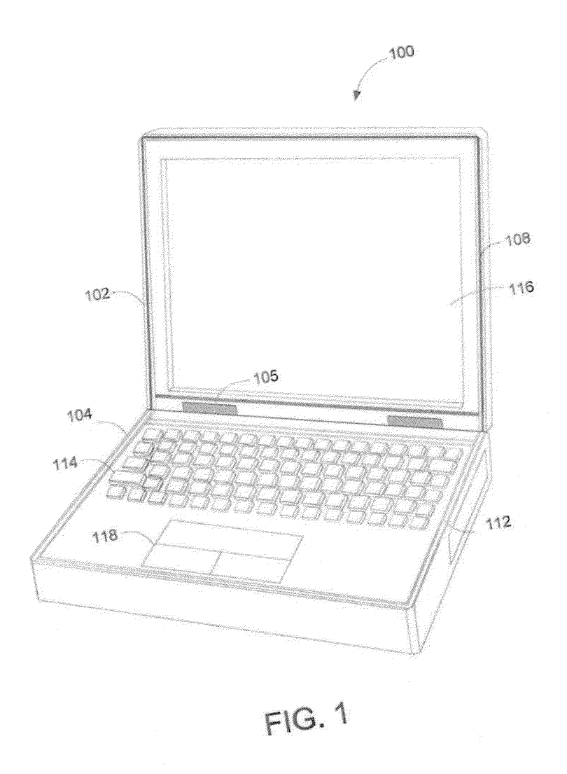

FIG. 1 is a three-dimensional perspective view of a notebook computer according to an embodiment of the present invention. According to one embodiment, the notebook computer 100 includes a tap housing 102 and lower housing 104 connected at a common end via a pivot mechanism 105 (e.g. hinge). In the present embodiment, the notebook computer is shown in an open position, in which the top housing is positioned away from the lower housing 104. The top housing 102 may represent a display panel and include a display 116 for presenting graphical images to a user operating the notebook computer 100. The lower housing 104 includes input interfaces such as a keyboard 114 and a track pad 118 formed on a top surface. Furthermore, a male engaging member 108 is formed continuously around the perimeter edges of an interior surface, or display surface, of the top housing 102. Similarly, a female receiving member 112 is formed continuously around the perimeter edges of the interior surface, or input interface surface, of the lower housing 104 in a position that corresponds with a position of the engaging member 108 formed around the top housing 102. As shown in FIG. 1, the male engaging member 108 and the female receiving member 112 are formed around all four sides and perimeter edges of interior surfaces of the top housing 102 and lower housing 104 respectively. Together the male engaging member 108 and the female receiving member 112 represent a mechanical scaling mechanism and may be formed from any sheet material including rubber, plastic, silicon, neoprene, etc. A detailed discussion of the sealing mechanism will be described in further detail below.

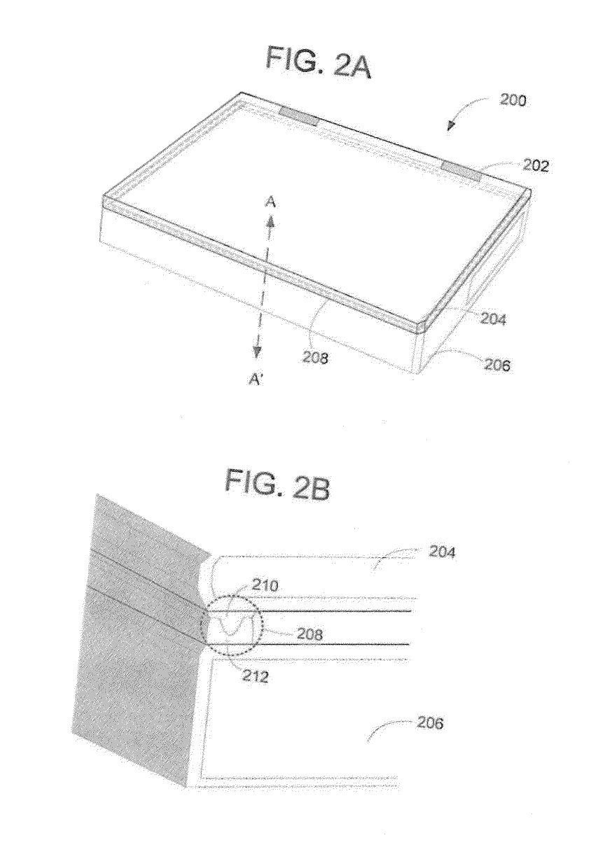

FIG. 2A is a three-dimensional perspective view of the portable electronic device in a closed position, while FIG. 2B is a three-dimensional cross-sectional view of the notebook computer taken along line A-A′ of FIG. 2A according to an embodiment of the present invention. As shown in FIG. 2A, notebook computer 200 includes a top housing 204 and a lower housing 206 connected via a pivot mechanism 202. In this exemplary embodiment, the top housing 204 is positioned above and vertically-aligned with the lower housing 206. Accordingly, the male receiving member of the top housing 204 and a corresponding female receiving member of the lower housing 206 mate together to form a hermetic seal 208. An exploded cross-sectional view of the hermetic seal is shown in FIG. 2B. As shown in this exemplary embodiment, the top housing 204 includes male engaging member 210, while the lower housing 206 includes female receiving member 212. When the notebook computer is in a closed position, or when the top housing is positioned directly above and vertically-aligned with the lower housing, the engaging member 210 and the receiving member 212 mate so as to form hermetic seal 208,

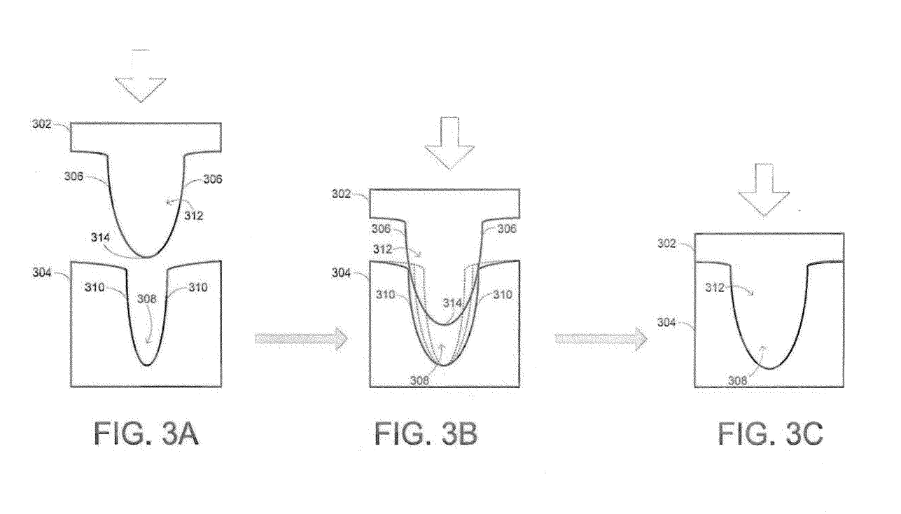

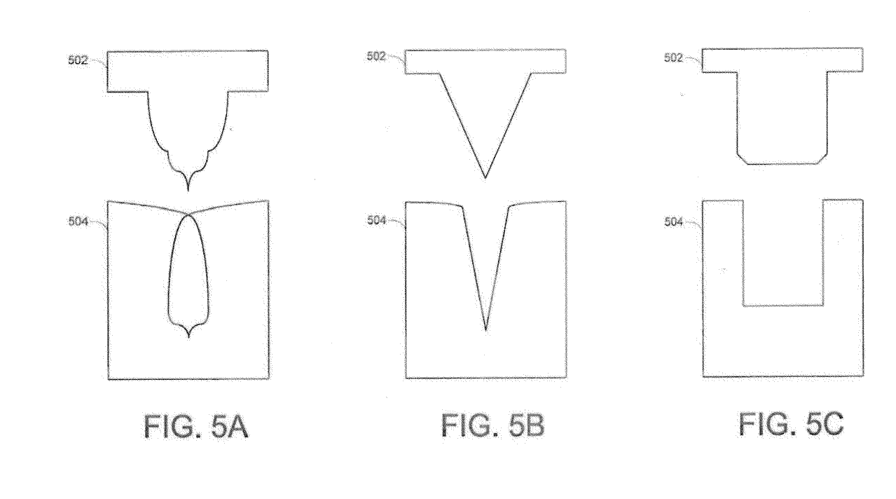

FIGS. 3A-3C illustrate the hermetic sealing process of the notebook computer according to an embodiment of the present invention. FIG. 3A depicts the male engaging member 302 positioned away from the female receiving member 304. Engaging member 302 includes a protruding portion 312 having two opposite exterior sides 306 and a tip area 314. Furthermore, receiving member 304 includes a concave area 308 for receiving the protruding portion 312 of the male engaging member 302, and two interior side walls 310 for engaging the exterior sides 306 of protruding portion 312. The opening of the concave area 308 may be wide enough such that the engaging member 302 and the receiving member 304 can be mated blindly, i.e. without a starting point. Though the illustrated embodiment depicts a rounded concave area 308 and tip area 314, the invention is not limited to thereto. For example, the tip area 314 of the protruding portion may be pointed or flat. Similarly, the concave area 308 may be formed to have a triangular or rectangular shape so as to correspond to the shape of the tip area 314 and protruding portion 312 of the engaging member 302. FIGS. 5A-5C depict alternative configurations of the male engaging member 502 and female receiving member 504 according to embodiments of the present invention. Moreover, the receiving member 504 shown in FIG. 5A is configured to have a small concave opening so as to help prevent external elements from the entering 502 the concave area of the receiving member 504 even when the notebook computer is in an open position.

FIG. 3B depicts the engaging member 302 being lowered into direct contact with the receiving member 304 as indicated by the downward force directional arrow. Further, as the tip area 314 of the protruding portion 312 enters the concave area 308 of the engaging member 302, the exterior sides 306 of the protruding portion engage the side walls 310 of the concave area 308. The downward force applied to the engaging member causes the side walls 310 of the concave area 308 to spread in opposing directions so as to open and receive the protruding portion 312. As a result, the exterior sides 306 of the protruding portion 312 rub along the side walls 310 of the concave area 308 until the tip area 314 of the protruding portion reaches the bottom of the concave area 308 of the receiving member 304. The completed hermetic seal is depicted in FIG. 3C in which the protruding portion 312 of the engaging member 302 is congruent with the concave area 308 of the receiving member 304. As shown in this exemplary embodiment, the receiving member 302 and engaging member 304 are mated together and form a hermetic or air-tight seal.

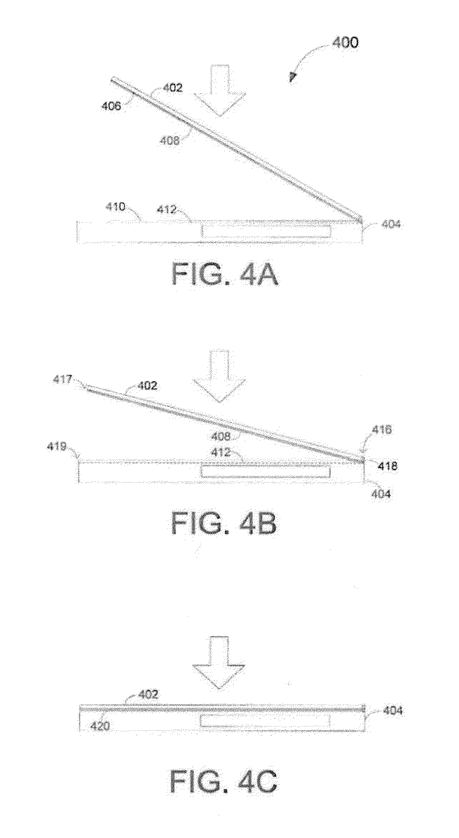

FIGS. 4A-4C illustrate the reps for automatically sealing the top and lower housings of the notebook computer according to an embodiment of the present invention. FIG. 4A depicts a notebook computer 400 in an open position in which the top housing 402 is positioned away from the lower housing 404. As shown here, the top housing 402 includes an inner surface 406 and an engaging member 408 formed thereon. The lower housing 404 includes an inner surface 410 and a receiving member 411 as indicated by dotted lines, formed thereon.

Referring now to FIG. 4B, this illustration depicts the top housing 402 being lowered onto the lower housing 404. According to one embodiment, a rear portion of the engaging member 408 closest to a common end 416 of the top housing 402 and lower housing 404, engages and mates with a rear portion of the receiving member 412 of the lower housing so as to form a first hermetic seal portion 418. As a front area 417 of the top housing 402 is lowered onto a front area 419 of the lower housing 404, the remaining, or unmated portions of the engaging member 408 are configured to engage and mate with the unmated portions of the receiving member 404. More particularly, the first hermetic seal portion 418 serves as a starting point for the unmated portions of the receiving member 404 to open and receive the unmated portions of the engaging member 408. Accordingly, portions of the male engaging member 408 progressively mate with portions of the receiving member 412 starting from the common end 418 of the notebook computer to the front area 419 of the lower housing as the notebook computer is placed in a closed position as depicted in FIG. 4C. As such, complete engagement of the engaging member 408 and the receiving member 412 is accomplished automatically, or without continuous downward pressure from the user around perimeter edges of the notebook computer. Furthermore, and as shown in FIG. 4C, the top housing 402 is formed directly above and vertically-aligned with the lower housing 404 so as to form a complete hermetic seal 420 between the engaging member 408 and receiving member 412. In a like manner, the engaging member 408 is automatically disengaged from the receiving member 412 simply by lifting or separating the top housing 402 from the lower housing 404.

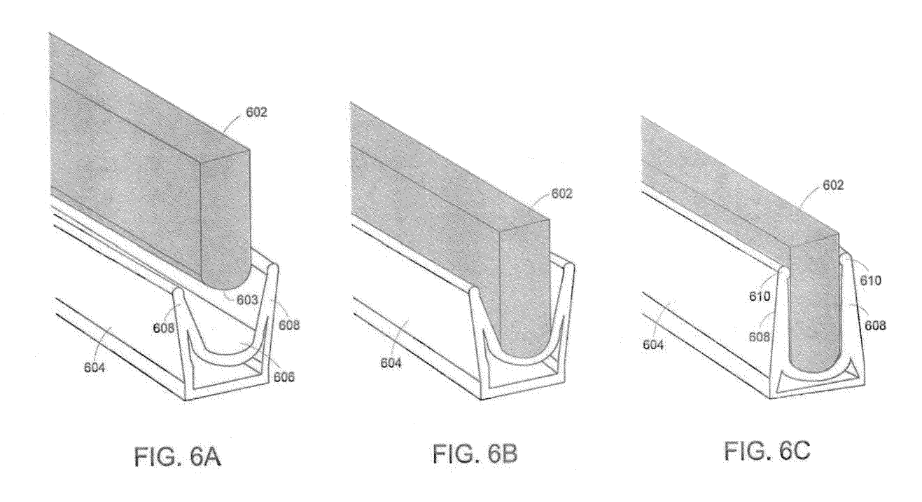

FIGS. 6A-6C illustrate an engagement member and receiving member according to another embodiment of the present invention. As shown in FIG. 6A, engaging member 602 includes a tip portion 603, while receiving member 604 includes a concave area 606 and a two side walls 608. Here, the receiving member 604 is in an open position in which the side walls 608 extend diagonally away from each other. FIG. 6B depicts the engaging member 602 extending downward into the receiving member 604 such that such the tip portion 603 of the engaging member 602 abuts the bottom of the concave area 606. Furthermore, as the more downward pressure is applied, the engaging member 602 presses on the concave area 606 of the receiving member 604 and causes the side waits to contract and come together as shown in FIG. 6C. When the receiving member is in the closed position shown in FIG. 6C, the side walls 608 of the receiving member 604 lie substantially parallel to the sides of the engaging member 602. Moreover, as the side walls 608 come together, upper gripping portions 610 of the receiving member 604 eventually abut and clamp onto the sides of the engaging member 602 so as-to seal the engaging member 602 within the receiving member 604. Accordingly, a hermetic seal can be formed continuously around the perimeter edges of the notebook computer.

Embodiments of the present invention provide a hermetic seal for a portable electronic device. In particular, a mechanical sealing mechanism is provided that allows the housings of a portable electronic device to be scaled around a perimeter edge. Accordingly, users are able to quickly and effortlessly protect critical components of the portable electronic device when in a closed position.

Many advantages are afforded by the perimeter edge hermetic seal according to embodiments of the present invention. For instance, electronically harmful elements such as dust and water are unable to enter and affect circuitry related to the LCD keyboard, touchpad, and speakers of the portable electronic device, without adding additional weight and complexity to the device. Additionally, the hermetic seal may be transparent to the user, and is engaged and disengaged just by closing and opening the portable electronic device. By keeping external artifacts out of the display and keyboard surface area when the device is in a closed state, the build-up of contaminates in this area is thereby prevented. As such, the integrity of the system is consistently maintained, and unnecessary cleaning or maintenance can be avoided.

Furthermore, while the invention has been described with respect to exemplary embodiments, one skilled in the art will recognize that numerous modifications are possible. For example, although exemplary embodiments depict a notebook computer as the portable electronic device, the invention is not limited thereto. For example, the portable electronic device may be a netbook, a tablet personal computer, a cell phone, or any other electronic device having a clam shell housing arrangement.

Furthermore, the engaging member may be formed on the lower housing as opposed to the top housing as described in the embodiments discussed above. Similarly, the female receiving member may be formed on the top housing as opposed to the lower housing as described in the embodiments discussed above. Thus, although the invention has been described with respect to exemplary embodiments, it will be appreciated that the invention is intended to cover all modifications and equivalents within the scope of the following claims.

What is claimed is:

1. A portable electronic device comprising:
a first housing and a second housing coupled at a common end;
an engaging member formed continuously around an interior surface of the first housing; and
a receiving member formed continuously around an interior surface of the second housing,
wherein the engaging member is configured to fit hermetically within the receiving member so as to seal the first housing with the second housing.

2. The portable electronic device of claim 1, wherein when a portion of the engaging member abuts a corresponding portion of the receiving member, the portion of the engaging member and the portion of receiving member automatically mate together.

3. The portable electronic device of claim 1, wherein the engaging member includes a protruding portion having two exterior sides and a tip area, and
wherein the receiving member includes a concave area having two side walls.

4. The portable electronic device of claim 3, wherein when the tip area of the protruding portion reaches the bottom of the concave area of the receiving member, a hermetic seal is formed between the first housing and the second housing.

5. The portable electronic device of claim 4, wherein when the first housing is lowered onto the second housing, the exterior sides of the protruding portion of the engaging member are adapted to expand the side walls of the receiving member such that the side wails of the receiving member rub along exterior sides of the protruding portion.

6. The portable electronic device of claim 3, wherein the side walls of the receiving member are configured to contract and come toward each other as a bottom portion of the engaging member presses into the concave area of the receiving member such that at least a portion of each of the side walls of the receiving member clamp onto the exterior sides of the engaging member.

7. The portable electronic device of claim 1, wherein the first housing is positioned above and vertically-aligned with the second housing when the portable electronic device is in a closed position.

8. The portable electronic device of claim 7, wherein the engaging member and the receiving member are configured to automatically disengage by separating the lust housing from the second housing when the portable electronic device is in the closed position.

9. The portable electronic device of claim wherein the engaging member and the receiving member are configured to automatically engage starting from the common end of the first housing and the second housing to an end opposite the common end.

10. A method for forming an air-tight seal for a portable electronic device having a top housing and a lower housing connected at a common end the method comprising:
lowering the top housing onto the lower housing so that an engaging member formed. continuously around an interior surface of the top housing fits hermetically within a receiving member formed continuously around an interior surface of the lower housing.

11. The method of claim 10, wherein when a portion oldie engaging member abuts a corresponding portion of the receiving member, the portion of the engaging member and the corresponding portion of the receiving member automatically mate together.

12. The method of claim 10, wherein the engaging member includes a protruding portion having two exterior sides arid a tip area, and
wherein the receiving member includes a concave area having two side walls.

13. The method of claim 12, wherein the lowering step comprises:
expanding the side walls of the concave area of the receiving member via the exterior sides of the protruding portion of the engaging member as the top housing is lowered onto the lower housing.

14. The method of claim 12, wherein the lowering step comprises:
contracting the side walls of the receiving member toward each other as a bottom portion of the engaging member presses into the concave area of the receiving member.

15. The method of claim 10, wherein the engaging member and the receiving member are configured u automatically engage starting from the common end of the first housing and the second housing to an end opposite the common end.
